(19) United States
(12) Patent Application Publication
(10) Pub. No.: US 2025/0006758 A1
(43) Pub. Date: Jan. 2, 2025

(54) IMAGING ELEMENT AND ELECTRONIC APPARATUS

(71) Applicant: SONY SEMICONDUCTOR SOLUTIONS CORPORATION, KANAGAWA (JP)

(72) Inventor: YUMA ONO, KANAGAWA (JP)

(21) Appl. No.: 18/705,631

(22) PCT Filed: Oct. 24, 2022
(86) PCT No.: PCT/JP2022/039462

§ 371 Date: Apr. 29, 2024

(30) Foreign Application Priority Data
Nov. 5, 2021 (JP) 2021-180819

(51) Int. Cl. H01L 27/146

(52) U.S. Cl. CPC H01L 27/14623; H01L 27/14645

(57) ABSTRACT

The present technology relates to an imaging element and an electronic apparatus that can suppress color mixture. The imaging element includes a first photoelectric converter that generates a charge corresponding to an amount of light, a second photoelectric converter that has a smaller light-receiving area than the first photoelectric converter, and a light-blocking wall provided between adjacent pixels. The light-blocking wall is provided in a shape having a spaced-apart region. The region is a region where light-blocking walls intersect in a case where the light-blocking walls are provided. The light-blocking wall is provided on each side of the first photoelectric converter, one end of the light-blocking wall serves as a region, and the other end is connected to another light-blocking wall. The present technology can be applied to an imaging element that acquires an image having an expanded dynamic range by using large pixels and small pixels.

### TECHNICAL FIELD

The present technology relates to an imaging element and an electronic apparatus, and for example, to an imaging element and an electronic apparatus that can suppress color mixture.

### BACKGROUND ART

Conventionally, as a method for generating wide dynamic range images, a method of providing a first pixel and a second pixel having mutually different sensitivities on a pixel array such as a complementary metal-oxide semiconductor (CMOS) image sensor and combining a first image and a second image including the outputs from the respective pixels is known.

Here, methods of providing pixels having different sensitivities include, for example, a method of providing pixels having long exposure times and pixels having short exposure times and a method of providing pixels having large-size photoelectric converters such as photodiodes (PDs) (hereinafter referred to as large pixels) and pixels having small-size photoelectric converters (hereinafter referred to as small pixels) (for example, see PTL 1).

### CITATION LIST

### Patent Literature

### PTL 1 JP 2017-163010 A

### SUMMARY

### Technical Problem

In the case of a configuration in which large pixels and small pixels with different sensitivities are provided, since the small pixels handle a large amount of light, it is desirable to avoid large color mixture coming from the large pixels with a large area. In addition, since large pixels handle a small amount of light, it is important to avoid small color mixture coming from small pixels. It is desirable to prevent light from leaking into adjacent pixels for both large and small pixels.

The present technology has been made in view of such a situation and is intended to prevent light from leaking into adjacent pixels.

### Solution to Problem

An imaging element according to one aspect of the present technology includes: a first photoelectric converter that generates a charge corresponding to an amount of light; a second photoelectric converter having a smaller light-receiving area than the first photoelectric converter; and a light-blocking wall provided between adjacent pixels, in which the light-blocking wall is provided in a shape having a spaced-apart region.

An electronic apparatus according to one aspect of the present technology includes: an imaging element including a first photoelectric converter that generates a charge corresponding to an amount of light, a second photoelectric converter having a smaller light-receiving area than the first photoelectric converter, and a light-blocking wall provided between adjacent pixels, the light-blocking wall being provided in a shape having a spaced-apart region; and a processor that processes signals from the imaging element.

The imaging element according to one aspect of the present technology includes: a first photoelectric converter that generates a charge corresponding to the amount of light; a second photoelectric converter that has a smaller light-receiving area than the first photoelectric converter; and a light-blocking wall provided between adjacent pixels. The light-blocking wall is provided in a shape having a spaced-apart region.

An electronic apparatus according to one aspect of the present technology is configured to include the imaging element.

The electronic apparatus may be an independent device or an internal block constituting a single device.

### BRIEF DESCRIPTION OF DRAWINGS

FIG. 1 is a diagram showing the configuration of an embodiment of an imaging device to which the present technology is applied.

FIG. 2 is a circuit diagram of a unit pixel.

FIG. 3 is a diagram for explaining unit pixels arranged in a pixel array unit.

FIG. 4 is a diagram showing the configuration of a unit pixel in a first embodiment.

FIG. 5 is a diagram for explaining a micro-loading effect.

FIG. 6 is a diagram showing the configuration of a unit pixel in a second embodiment.

FIG. 7 is a diagram showing the configuration of a unit pixel in a third embodiment.

FIG. 8 is a diagram showing the configuration of a unit pixel in a fourth embodiment.

FIG. 9 is a diagram showing another example of the configuration of a unit pixel.

FIG. 10 is a diagram showing the configuration of a unit pixel in a fifth embodiment.

FIG. 11 is a diagram showing the configuration of a unit pixel in a sixth embodiment.

FIG. 12 is a diagram showing an exemplary configuration of an electronic apparatus.

FIG. 13 is a block diagram showing an example of a schematic configuration of a vehicle control system.

FIG. 14 is an explanatory diagram showing an example of the installation positions of a vehicle exterior information detection unit and an imaging unit.

### DESCRIPTION OF EMBODIMENTS

Hereinafter, modes for carrying out the present technique (hereinafter referred to as “embodiments”) will be described.

### Configuration of Imaging Device

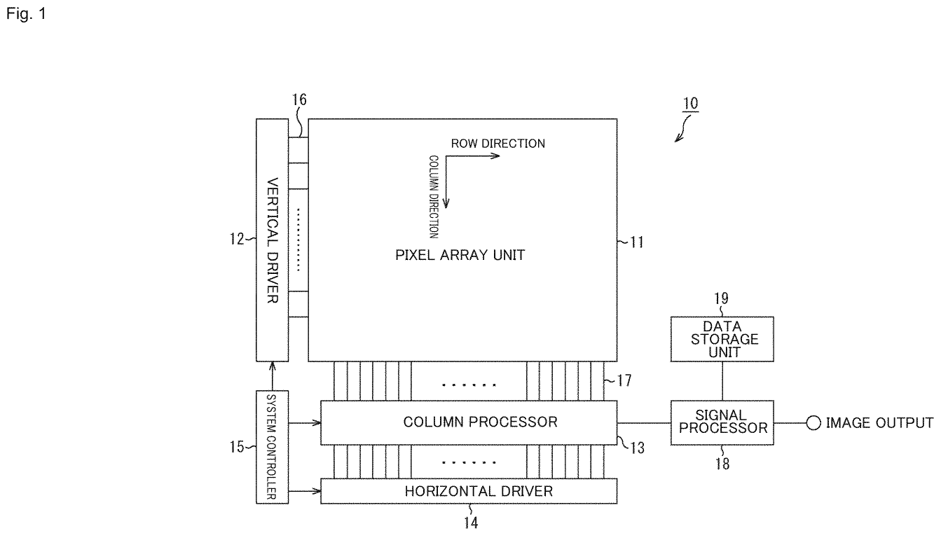

FIG. 1 is a system configuration diagram schematically showing the configuration of an imaging device to which the present technology is applied, for example, a CMOS image sensor which is a type of X-Y address-type imaging device. Here, the CMOS image sensor is an image sensor created by applying or partially using a CMOS process. For example, the imaging device is configured with a back-illuminated CMOS image sensor.

The imaging device 10 has a pixel array unit 11 formed on a semiconductor substrate (chip) (not shown), and a peripheral circuit unit integrated on the same semiconductor substrate as the pixel array unit 11. The peripheral circuit portion includes, for example, a vertical driver 12, a column processor 13, a horizontal driver 14, and a system controller 15.

The imaging device 10 further includes a signal processor 18 and a data storage unit 19. Each processing in the signal processor 18 and data storage unit 19 is performed by an external signal processor provided on a substrate other than the imaging device 10, such as a digital signal processor (DSP) circuit or software.

In the pixel array unit 11, unit pixels (hereinafter sometimes simply referred to as “pixels”) each having a photoelectric converter that generates and accumulates charges corresponding to the amount of received light are arranged two-dimensionally in row and column directions, that is, in a matrix. Here, the row direction refers to the arrangement direction of pixels in a pixel row (that is, the horizontal direction), and the column direction refers to the arrangement direction of pixels in a pixel column (that is, the vertical direction). Details of a specific circuit configuration and a pixel structure of the unit pixels will be described later.

In the pixel array unit 11, for a matrix-like pixel arrangement, a pixel drive line 16 is wired along the row direction for each pixel row, and a vertical signal line 17 is wired along the column direction for each pixel column. The pixel drive line 16 transmits a drive signal for performing driving at the time of reading out a signal from the pixel. In FIG. 1, one wiring is illustrated for the pixel drive line 16, but the number of wirings is not limited to one. One end of the pixel drive line 16 is connected to an output terminal of the vertical driver 12 corresponding to each row.

The vertical driver 12, which is constituted by a shift register, an address decoder, or the like, drives all of the pixels of the pixel array unit 11 at the same time, in units of rows, or the like. That is, the vertical driver 12 constitutes a driver that controls the operation of each pixel of the pixel array unit 11, together with the system controller 15 that controls the vertical driver 12. The vertical driver 12 generally has two scanning systems, a readout scanning system and a sweep scanning system, although the detailed configuration thereof is not shown in the drawings.

The readout scanning system sequentially selectively scans the unit pixels of the pixel array unit 11 in units of rows in order to read out signals from the unit pixels. The signals read from the unit pixels are analog signals. The sweep scanning system performs sweep scanning on read rows on which readout scanning is performed by the readout scanning system an exposure time in advance of the readout scanning.

By the sweep scanning performed by the sweep scanning system, unnecessary charges are swept out from the photoelectric converter of the unit pixel in the readout row, whereby the photoelectric converter is reset. By sweeping out (resetting) unnecessary charges by this sweep scanning system, a so-called electronic shutter operation is performed. Here, the electronic shutter operation refers to an operation of discarding the charge of the photoelectric converter and starting a new exposure (starting accumulation of charge).

A signal read through the reading operation in the reading scanning system corresponds to the amount of light received after the immediately previous reading operation or the electronic shutter operation. In addition, a period from a read timing in the immediately previous read operation or a sweep timing in the electronic shutter operation to a read timing in a current read operation is a charge exposure period in the unit pixel.

The signals output from each unit pixel in the pixel row selectively scanned by the vertical driver 12 are input to the column processor 13 through each of the vertical signal lines 17 for each pixel column. The column processor 13 performs predetermined signal processing on the signal output from each pixel of the selected row through the vertical signal line 17 for each pixel column of the pixel array unit 11, and temporarily holds the pixel signal after the signal processing.

Specifically, the column processor 13 performs at least noise removal processing, such as correlated double sampling (CDS) processing and double data sampling (DDS) processing, as signal processing. For example, the CDS processing removes pixel-specific fixed pattern noise such as reset noise and threshold variation of amplification transistors within the pixel. In addition to the noise removal processing, the column processor 13 can also have, for example, an analog-digital (AD) conversion function to convert an analog pixel signal into a digital signal and output the digital signal.

The horizontal driver 14 is configured with a shift register, an address decoder, or the like and selects the unit circuits corresponding to the pixel column of the column processor 13 in sequence. Through selective scanning by the horizontal driver 14, pixel signals subjected to the signal processing for each unit circuit in the column processing portion 13 are sequentially output.

The system controller 15 includes, for example, a timing generator that generates various timing signals, and performs control of driving of the vertical driver 12, the column processor 13, the horizontal driver 14, and the like on the basis of the various timing signals generated by the timing generator.

The signal processor 18 has at least a calculation processing function and performs various signal processing such as calculation processing on a pixel signal output from the column processor 13. The data storage unit 19 temporarily stores data required for signal processing in the signal processor 18.

### Circuit Configuration of Unit Pixel

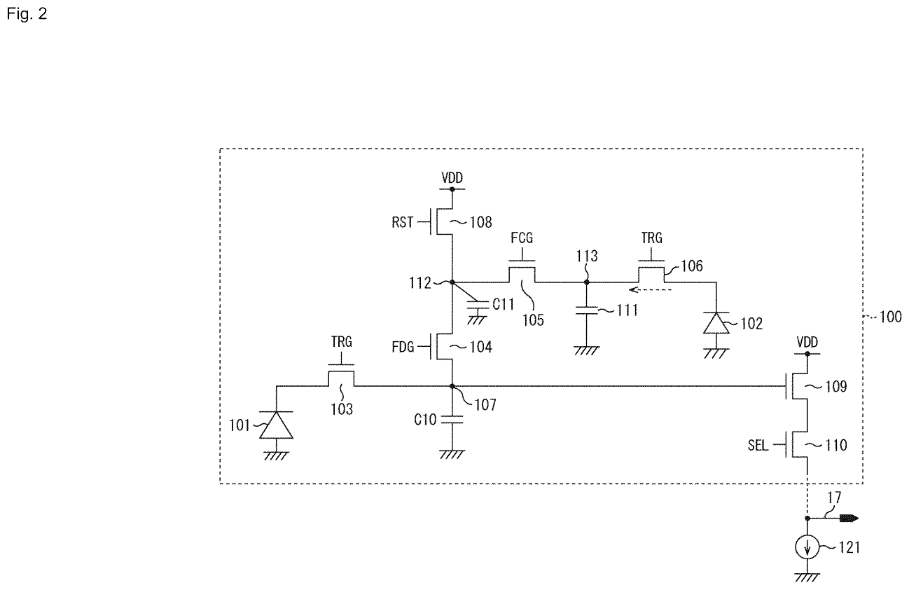

FIG. 2 is a circuit diagram showing a configuration example of the unit pixel 100 arranged in the pixel array unit 11 of FIG. 1.

The unit pixel 100 includes a first photoelectric converter 101, a second photoelectric converter 102, a first transfer transistor 103, a second transfer transistor 104, a third transfer transistor 105, a fourth transfer transistor 106, a floating diffusion (FD) unit 107, a reset transistor 108, an amplification transistor 109, and a selection transistor 110.

The reset transistor 108 and the amplification transistor 109 are connected to a power supply VDD. The first photoelectric converter 101 includes a so-called embedded photodiode in which an n-type impurity region is formed inside a p-type impurity region formed in a silicon semiconductor substrate. Similarly, the second photoelectric converter 102 includes an embedded photodiode. The first photoelectric converter 101 and the second photoelectric converter 102 generate signal charges corresponding to the amount of received light and accumulate the generated charges up to a certain amount.

The unit pixel 100 further includes a charge accumulation unit 111. The charge accumulation unit 111 is, for example, a MOS capacitor or an MIS capacitor.

In FIG. 2, a first transfer transistor 103, a second transfer transistor 104, a third transfer transistor 105, and a fourth transfer transistor 106 are connected in series between the first photoelectric converter 101 and the second photoelectric converter 102. A floating diffusion layer connected between the first transfer transistor 103 and the second transfer transistor 104 corresponds to the FD unit 107. The FD unit 107 includes a parasitic capacitance C10.

A floating diffusion layer connected between the second transfer transistor 104 and the third transfer transistor 105 corresponds to a node 112. The node 112 is provided with a parasitic capacitance C11. A floating diffusion layer connected between the third transfer transistor 105 and the fourth transfer transistor 106 corresponds to a node 113. The charge accumulation unit 111 is connected to the node 113.

For the unit pixel 100, a plurality of drive lines are wired as the pixel drive lines 16 in FIG. 1, for example, for each pixel row. Various drive signals TGL, FDG, FCG, TGS, RST, and SEL are supplied from the vertical driver 12 in FIG. 1 via a plurality of drive lines. Since each transistor of the unit pixel 100 is an NMOS transistor, these drive signals are pulse signals in which a high-level state (for example, power supply voltage VDD) corresponds to an active state, and a low-level state (for example, negative potential) corresponds to an inactive state.

A drive signal TGL is applied to the gate electrode of the first transfer transistor 103. When the drive signal TGL becomes active, the first transfer transistor 103 becomes conductive, and the charges accumulated in the first photoelectric converter 101 are transferred to the FD unit 107 via the first transfer transistor 103.

A drive signal FDG is applied to the gate electrode of the second transfer transistor 104. When the drive signal FDG becomes active and the second transfer transistor 104 becomes conductive, the potentials of the FD unit 107 and the node 112 are combined to form one charge accumulation region.

A drive signal FCG is applied to the gate electrode of the third transfer transistor 105. When the drive signal FDG and the drive signal FCG become active and the second transfer transistor 104 and the third transfer transistor 105 become conductive, the potentials of the FD unit 107 and the charge accumulation unit 111 are combined to form one charge accumulation region.

A drive signal TGS is applied to the gate electrode of the fourth transfer transistor 106. When the drive signal TGS becomes active, the fourth transfer transistor 106 becomes conductive, and the charges accumulated in the second photoelectric converter 102 are transferred to the charge accumulation unit 111 via the fourth transfer transistor 106. When the fourth transfer transistor 106, the third transfer transistor 105, and the second transfer transistor 104 are in the active state, the potentials of the charge accumulation unit 111 and the FD unit 107 are combined, and the charges accumulated in the second photoelectric converter 102 are transferred to the combined charge accumulation region.

Furthermore, the potential of the channel region under the gate electrode of the fourth transfer transistor 106 is slightly closer to the positive side than the channel region under the gate electrode of the first transfer transistor 103, the second transfer transistor 104, or the third transfer transistor 105, for example (in other words, the potential is slightly deeper), whereby a charge overflow path is formed. As a result of photoelectric conversion in the second photoelectric converter 102, if charges exceeding the saturation charge amount of the second photoelectric converter 102 are generated, the charges exceeding the saturation charge amount overflow from the second photoelectric converter 102 to the charge accumulation unit 111 via the overflow path. The overflowed charges are accumulated in the charge accumulation unit 111.

Note that, hereinafter, the overflow path formed in the channel region below the gate electrode of the fourth transfer transistor 106 will be simply referred to as an overflow path of the fourth transfer transistor 106.

In FIG. 2, among the two electrodes of the charge accumulation unit 111, the first electrode is a node electrode connected to the node 113 between the third transfer transistor 105 and the fourth transfer transistor 106. Among the two electrodes of the charge accumulation unit 111, the second electrode is a ground electrode.

Note that, as a modification, the second electrode may be connected to a specific potential other than the ground potential, for example, a power supply potential.

When the charge accumulation unit 111 is a MOS capacitor or an MIS capacitor, for example, the second electrode is an impurity region formed on a silicon substrate, and a dielectric film forming the capacitor is an oxide film or a nitride film formed on the silicon substrate. The first electrode is an electrode formed of a conductive material such as polysilicon or metal above the second electrode and the dielectric film.

When the second electrode is set to the ground potential, the second electrode may be a p-type impurity region electrically connected to a p-type impurity region provided in the first photoelectric converter 101 or the second photoelectric converter 102. When the second electrode is set to a specific potential other than the ground potential, the second electrode may be an n-type impurity region formed within a p-type impurity region.

In addition to the second transfer transistor 104, the reset transistor 108 is also connected to the node 112. A specific potential, such as a power supply potential VDD, is connected to the tip of the reset transistor. The drive signal RST is applied to the gate electrode of the reset transistor 108. When the drive signal RST becomes active, the reset transistor 108 becomes conductive, and the potential of the node 112 is reset to the level of the voltage VDD.

When the drive signal RST is activated, if the drive signal FDG of the second transfer transistor 104 and the drive signal FCG of the third transfer transistor 105 are activated, the combined potential of the node 112, the FD unit 107, and the charge accumulation unit 111 is reset to the level of the voltage VDD.

Note that by individually controlling the drive signal FDG and the drive signal FCG, the potentials of the FD unit 107 and the charge accumulation unit 111 may be individually (independently) reset to the level of the voltage VDD.

The FD unit 107, which is a floating diffusion layer, is a charge-voltage conversion means. That is, when charges are transferred to the FD unit 107, the potential of the FD unit 107 changes depending on the amount of transferred charges.

A current source 121 connected to one end of the vertical signal line 17 is connected to the source side of the amplification transistor 109 and the power supply VDD is connected to the drain side, whereby the amplification transistor 109 forms a source follower circuit together with the current source 121 and the power supply VDD. The FD unit 107 is connected to the gate electrode of the amplification transistor 109 and serves as an input to the source follower circuit.

The selection transistor 110 is connected between the source of the amplification transistor 109 and the vertical signal line 17. The drive signal SEL is applied to the gate electrode of the selection transistor 110. When the drive signal SEL becomes active, the selection transistor 110 becomes conductive, and the unit pixel 100 enters a selected state.

When the charges are transferred to the FD unit 107, the potential of the FD unit 107 reaches a potential corresponding to the amount of transferred charges, and this potential is input to the source follower circuit described above. When the drive signal SEL becomes active, the potential of the FD unit 107 corresponding to the amount of charge is output to the vertical signal line 17 via the selection transistor 110 as an output of the source follower circuit.

The first photoelectric converter 101 has a photodiode having a wider light-receiving area than the second photoelectric converter 102. Therefore, when a subject with a predetermined illuminance is photographed in a predetermined exposure time, the charges generated in the first photoelectric converter 101 are greater than the charges generated in the second photoelectric converter 102.

Therefore, when the charges generated in the first photoelectric converter 101 and the charges generated in the second photoelectric converter 102 are transferred to the FD unit 107 and subjected to charge-voltage conversion, the change in voltage before and after the charges generated in the first photoelectric converter 101 are transferred to the FD unit 107 is larger than the change in voltage before and after the charges generated in the second photoelectric converter 102 are transferred to the FD unit 107. Therefore, when the first photoelectric converter 101 and the second photoelectric converter 102 are compared, the first photoelectric converter 101 has higher sensitivity than the second photoelectric converter 102.

On the other hand, even if high illuminance light is incident on the second photoelectric converter 102 and charges exceeding the saturation charge amount of the second photoelectric converter 102 are generated, the charges generated exceeding the saturation charge amount can be accumulated in the charge accumulation unit 111. Thus, when the charges generated in the second photoelectric converter 102 are subjected to charge-voltage conversion, the charge-voltage conversion can be performed after adding the charges accumulated in the second photoelectric converter 102 and the charges accumulated in the charge accumulation unit 111.

As a result, the second photoelectric converter 102 can photograph an image with gradation over a wider illuminance range than the first photoelectric converter 101. In other words, the second photoelectric converter 102 can photograph an image with a wider dynamic range.

For example, two images, an image with high sensitivity photographed using the first photoelectric converter 101 and an image with a wide dynamic range photographed using the second photoelectric converter 102, are combined into one image through wide dynamic range image synthesis processing of synthesizing one image from two images by an image signal processing circuit provided inside the imaging device 10 or an image signal processing device connected to the outside of the imaging device 10.

### Configuration Example of Unit Pixel

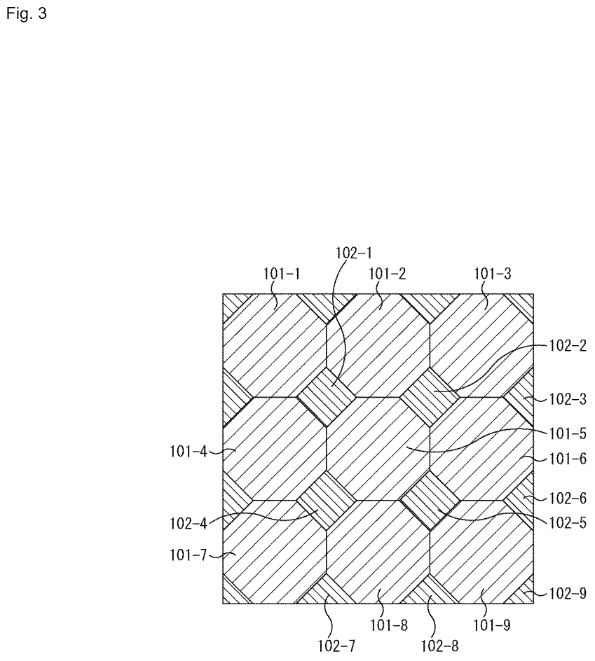

FIG. 3 is a diagram showing an example of the planar configuration of the unit pixels 100 arranged in the pixel array unit 11. FIG. 3 illustrates nine (3x3) unit pixels 100 arranged in the pixel array unit 11.

The unit pixel 100 includes a first photoelectric converter 101 formed in an octagonal shape and a second photoelectric converter 102 formed in a rectangular shape. In FIG. 3, the description will be continued assuming that the first photoelectric converter 101-1 shown at the upper left in the figure and the second photoelectric converter 102-1 provided at the lower right of the first photoelectric converter 101-1 constitute the unit pixel 100.

Similarly, a first photoelectric converter 101-2 shown above the center in the figure and a second photoelectric converter 102-2 provided at the lower right of the first photoelectric converter 101-2 constitute the unit pixel 100. Similarly, the first photoelectric converter 101-3 shown in the upper right of the figure and the second photoelectric converter 102-3 (only half shown in the figure) provided at the lower right of the first photoelectric converter 101-3 constitute the unit pixel 100.

Similarly, a set of a first photoelectric converter 101-4 and a second photoelectric converter 102-4, a set of a first photoelectric converter 101-5 and a second photoelectric converter 102-5, a set of a first photoelectric converter 101-6 and a second photoelectric converter 102-6, a set of a first photoelectric converter 101-7 and a second photoelectric converter 102-7, a set of a first photoelectric converter 101-8 and a second photoelectric converter 102-8, and a set of a first photoelectric converter 101-9 and a second photoelectric converter 102-9 each form the unit pixel 100.

The region surrounded by the four pixels of the first photoelectric converter 101-1, the first photoelectric converter 101-2, the first photoelectric converter 101-4, and the first photoelectric converter 101-5 corresponds to the second photoelectric converter 102-1. The first side of the second photoelectric converter 102-1 is in contact with one side of the first photoelectric converter 101-1, the second side of the second photoelectric converter 102-1 is in contact with one side of the first photoelectric converter 101-2, the third side of the second photoelectric converter 102-1 is in contact with one side of the first photoelectric converter 101-4, and the fourth side of the second photoelectric converter 102-1 is in contact with one side of the first photoelectric converter 101-5.

The other second photoelectric converter 102 is also surrounded by the octagonal first photoelectric converter 101 and is formed in a rectangular shape in which one side of the first photoelectric converter 101 corresponds to the second photoelectric converter 102.

Although the case where the first photoelectric converter 101 is a regular octagon is described as an example, it may be an octagon with different side lengths instead of a regular octagon.

Note that although the case where the first photoelectric converter 101 serving as a large pixel is formed in an octagonal shape will be described as an example, the present technology can be applied to shapes other than an octagonal shape. In addition, although the case where the second photoelectric converter 102 serving as a small pixel is formed in a rectangular shape, it can be changed as appropriate according to the shape of the first photoelectric converter 101.

A light-blocking wall is provided between adjacent first photoelectric converters 101. A light-blocking wall is also provided between the adjacent first photoelectric converter 101 and second photoelectric converter 102. The light-blocking wall is provided to prevent incident light from leaking into adjacent photoelectric converters. The light-blocking wall provided in the unit pixel 100 will be explained below.

### First Embodiment

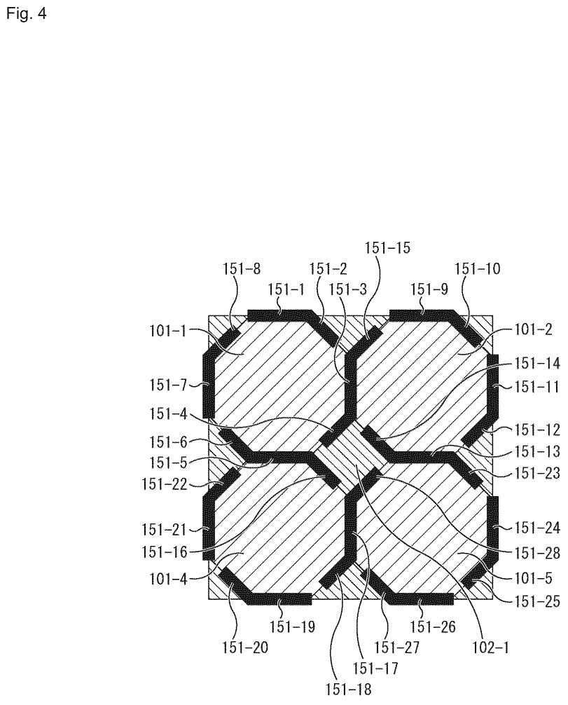

FIG. 4 is a diagram for explaining the configuration of the unit pixel 100 in the first embodiment. FIG. 4 shows 2×2 first photoelectric converters 101 among the 3x3 first photoelectric converters 101 shown in FIG. 3.

As shown in FIG. 4, the second photoelectric converter 102-1 is formed so as to be surrounded by four first photoelectric converters 101-1, 101-2, 101-4, and 101-5.

A light-blocking wall 151-1 is formed on the upper side of the first photoelectric converter 101-1 located at the upper left in the figure. A light-blocking wall 151-2 is formed on the upper right oblique side of the first photoelectric converter 101-1. The light-blocking wall 151-1 and the light-blocking wall 151-2 are formed in a continuous shape.

The light-blocking wall 151 is made of a light-blocking material and is formed at a depth described later in the semiconductor substrate on which the first photoelectric converter 101 and the second photoelectric converter 102 are provided. The light-blocking wall 151 is configured to contain metal such as aluminum or tungsten, for example.

A light-blocking wall 151-3 is formed on the right side of the first photoelectric converter 101-1. A light-blocking wall 151-4 is formed on the lower right oblique side of the first photoelectric converter 101-1. The light-blocking wall 151-3 and the light-blocking wall 151-4 are formed in a continuous shape.

A light-blocking wall 151-5 is formed on the lower side of the first photoelectric converter 101-1. A light-blocking wall 151-6 is formed on the lower left oblique side of the first photoelectric converter 101-1. The light-blocking wall 151-5 and the light-blocking wall 151-6 are formed in a continuous shape.

A light-blocking wall 151-7 is formed on the left side of the first photoelectric converter 101-1. A light-blocking wall 151-8 is formed on the upper left oblique side of the first photoelectric converter 101-1. The light-blocking wall 151-7 and the light-blocking wall 151-8 are formed in a continuous shape.

A light-blocking wall 151-9 is formed on the upper side of the first photoelectric converter 101-2 located at the upper right in the figure. A light-blocking wall 151-10 is formed on the upper right oblique side of the first photoelectric converter 101-2. The light-blocking wall 151-9 and the light-blocking wall 151-10 are formed in a continuous shape.

A light-blocking wall 151-11 is formed on the right side of the first photoelectric converter 101-2. A light-blocking wall 151-12 is formed on the lower right oblique side of the first photoelectric converter 101-2. The light-blocking wall 151-11 and the light-blocking wall 151-12 are formed in a continuous shape.

A light-blocking wall 151-13 is formed on the lower side of the first photoelectric converter 101-2. A light-blocking wall 151-14 is formed on the lower left oblique side of the first photoelectric converter 101-2. The light-blocking wall 151-13 and the light-blocking wall 151-14 are formed in a continuous shape.

A light-blocking wall 151-3 is formed on the left side of the first photoelectric converter 101-2 (the side between the first photoelectric converter 101-2 and the first photoelectric converter 101-1). A light-blocking wall 151-15 is formed on the upper left oblique side of the first photoelectric converter 101-2. The light-blocking wall 151-3 and the light-blocking wall 151-15 are formed in a continuous shape.

The light-blocking wall 151-15, the light-blocking wall 151-3, and the light-blocking wall 151-4 are formed in a continuous shape.

A light-blocking wall 151-5 is formed on the upper side of the first photoelectric converter 101-4 located at the lower left in the figure (the side between the first photoelectric converter 101-4 and the first photoelectric converter 101-1). A light-blocking wall 151-16 is formed on the upper right oblique side of the first photoelectric converter 101-4. The light-blocking wall 151-5 and the light-blocking wall 151-16 are formed in a continuous shape.

The light-blocking wall 151-16, the light-blocking wall 151-5, and the light-blocking wall 151-6 are formed in a continuous shape.

A light-blocking wall 151-17 is formed on the right side of the first photoelectric converter 101-4. A light-blocking wall 151-18 is formed on the lower right oblique side of the first photoelectric converter 101-4. The light-blocking wall 151-17 and the light-blocking wall 151-18 are formed in a continuous shape.

A light-blocking wall 151-19 is formed on the lower side of the first photoelectric converter 101-4. A light-blocking wall 151-20 is formed on the lower left oblique side of the first photoelectric converter 101-4. The light-blocking wall 151-19 and the light-blocking wall 151-20 are formed in a continuous shape.

A light-blocking wall 151-21 is formed on the left side of the first photoelectric converter 101-4. A light-blocking wall 151-22 is formed on the upper left oblique side of the first photoelectric converter 101-4. The light-blocking wall 151-21 and the light-blocking wall 151-22 are formed in a continuous shape.

A light-blocking wall 151-13 is formed on the upper side of the first photoelectric converter 101-5 located at the lower right in the figure (the side between the first photoelectric converter 101-5 and the first photoelectric converter 101-2). A light-blocking wall 151-23 is formed on the upper right oblique side of the first photoelectric converter 101-5. The light-blocking wall 151-13 and the light-blocking wall 151-23 are formed in a continuous shape.

The light-blocking wall 151-23, the light-blocking wall 151-13, and the light-blocking wall 151-14 are formed in a continuous shape.

A light-blocking wall 151-24 is formed on the right side of the first photoelectric converter 101-5. A light-blocking wall 151-25 is formed on the lower right oblique side of the first photoelectric converter 101-5. The light-blocking wall 151-24 and the light-blocking wall 151-25 are formed in a continuous shape.

A light-blocking wall 151-26 is formed on the lower side of the first photoelectric converter 101-5. A light-blocking wall 151-27 is formed on the lower left oblique side of the first photoelectric converter 101-5. The light-blocking wall 151-26 and the light-blocking wall 151-27 are formed in a continuous shape.

A light-blocking wall 151-17 is formed on the left side of the first photoelectric converter 101-5 (the side between the first photoelectric converter 101-5 and the first photoelectric converter 101-4). A light-blocking wall 151-28 is formed on the upper left oblique side of the first photoelectric converter 101-5. The light-blocking wall 151-17 and the light-blocking wall 151-28 are formed in a continuous shape.

The light-blocking wall 151-18, the light-blocking wall 151-17, and the light-blocking wall 151-28 are formed in a continuous shape.

A light-blocking wall 151-4 is formed between the upper left side of the second photoelectric converter 102-1 and the lower right oblique side of the first photoelectric converter 101-1. A light-blocking wall 151-14 is formed between the upper right side of the second photoelectric converter 102-1 and the lower left oblique side of the first photoelectric converter 101-2.

A light-blocking wall 151-28 is formed between the lower right side of the second photoelectric converter 102-1 and the upper left oblique side of the first photoelectric converter 101-5. A light-blocking wall 151-16 is formed between the lower left side of the second photoelectric converter 102-1 and the upper right oblique side of the first photoelectric converter 101-4.

The second photoelectric converter 102-1, which corresponds to a small pixel, is surrounded by a light-blocking wall 151 provided on each side of the first photoelectric converters 101-1, 101-2, 101-4, and 101-5 surrounding the second photoelectric converter 102-1.

In this way, the light-blocking wall 151 is formed on each of the eight sides of the octagonal first photoelectric converter 101. Similarly, when focusing on the second photoelectric converter 102, the light-blocking wall 151 is formed on each of the four sides of the second photoelectric converter 102.

The light-blocking wall 151 surrounding the first photoelectric converter 101 is formed so as to have a spaced-apart region. Referring again to FIG. 4, a region where the light-blocking wall 151 is not formed is provided between the light-blocking wall 151-2 and the light-blocking wall 151-3 provided in the first photoelectric converter 101-1. Similarly, a region where the light-blocking wall 151 is not formed is provided between the light-blocking wall 151-4 and the light-blocking wall 151-5. A region where the light-blocking wall 151 is not formed is provided between the light-blocking wall 151-6 and the light-blocking wall 151-7. A region where the light-blocking wall 151 is not formed is provided between the light-blocking wall 151-8 and the light-blocking wall 151-1.

Similarly to the first photoelectric converter 101-1, the light-blocking wall 151 surrounding the first photoelectric converters 101-2, 101-4, and 101-5 is formed in a state where a spaced-apart region is provided.

The light-blocking walls 151 provided on each side of the first photoelectric converter 101 are configured such that one end serves as a spaced-apart region and the other end is connected to another light-blocking wall 151. For example, a spaced-apart region is provided at one end of the light-blocking wall 151-1, and a light-blocking wall 152-2 is connected to the other end.

The light-blocking wall 151-4, the light-blocking wall 151-14, the light-blocking wall 151-28, and the light-blocking wall 151-16 surrounding the second photoelectric converter 102-2 are provided in a spaced-apart shape.

When focusing on the second photoelectric converter 102, the light-blocking walls 151 are formed radially around the second photoelectric converter 102. For example, referring to the second photoelectric converter 102-1 shown in FIG. 4, a first light-blocking wall 151 including a light-blocking wall 151-4, a light-blocking wall 151-3, and a light-blocking wall 151-15, a second light-blocking wall 151 including a light-blocking wall 151-14, a light-blocking wall 151-13, and a light-blocking wall 151-23, a third light-blocking wall 151 including a light-blocking wall 151-28, a light-blocking wall 151-17, and a light-blocking wall 151-18, and a fourth light-blocking wall 151 including a light-blocking wall 151-16, a light-blocking wall 151-5, and a light-blocking wall 151-6 are formed radially around the second photoelectric converter 102-2.

The region where the light-blocking walls 151 are spaced apart is a region where the light-blocking walls 151 are not formed. A region where the light-blocking wall 151 is not formed is a region where three light-blocking walls 151 would intersect if the light-blocking walls 151 were formed without being spaced apart. For example, when the light-blocking wall 151-2 and the light-blocking wall 151-3 are configured not to be spaced apart, the region is a region where the light-blocking wall 151-2, the light-blocking wall 151-3, and the light-blocking wall 151-15 intersect.

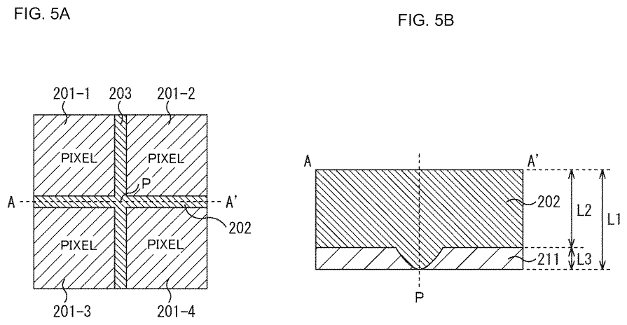

The light-blocking walls 151 are provided in such a region where the light-blocking walls 151 may intersect. If the light-blocking wall 151 is also provided at the intersections of the light-blocking walls 151, it may not be possible to process them to a uniform depth, and the ability to suppress color mixture may deteriorate. This will be described with reference to FIG. 5.

FIG. 5A is a diagram showing an example of a conventional planar configuration of a pixel, and FIG. 5B is a diagram showing an example of a cross-sectional configuration of a pixel along line segment A-A′ in FIG. 5A. As shown in FIG. 5A, pixels 201-1 to 201-4 are arranged in an array. A light-blocking wall 202 and a light-blocking wall 203 are formed between the pixels 201. The light-blocking wall 202 is formed in the horizontal direction in the figure, and the light-blocking wall 203 is formed in the vertical direction in the figure.

A light-blocking wall 202 is formed in the line segment A-A′. Referring to the cross-sectional configuration example of FIG. 5B, the light-blocking wall 202 is formed by forming a trench in the semiconductor substrate 211 and filling the trench with a light-blocking material or an insulating material.

A region where the light-blocking wall 202 and the light-blocking wall 203 intersect is defined as a region P. In FIG. 5B, the middle corresponds to the region P. When a trench is formed in the semiconductor substrate 211, the region P where the light-blocking wall 202 and the light-blocking wall 203 intersect is dug from the surface of the semiconductor substrate 211 to a depth L1 in the depth direction, for example. A trench formed in a region other than the region P is dug from the surface of the semiconductor substrate 211 to a depth L2 in the depth direction. Depth L1 and depth L2 are depths that satisfy the relationship of depth L1>depth L2.

During trench processing, due to the micro-loading effect, the region P where the light-blocking walls 202 and 203 intersect may be dug deeper than the region where the light-blocking walls do not intersect.

In the example shown in FIG. 5, since the region P is processed to depth L1, this depth L1 corresponds to the processing limit. The region P is processed to depth L1, but regions other than the region P are processed only to depth L2. In other words, there is a possibility that processing cannot be performed to a uniform depth, and the processing may end up with some deep regions.

As shown in FIG. 5B, when there are regions processed to depth L1 and a region processed to depth L2, in other words, the trench is not processed to a uniform depth, there is a possibility that a trench is not dug in the semiconductor substrate 211 and a region having depth L3 in which the light-blocking wall 202 is not formed may exist. In this region of depth L3, in other words, in the region where the light-blocking wall 202 is formed shallowly, there is a possibility that light may leak into adjacent pixels.

As described with reference to FIG. 3, in the case of a structure in which the first photoelectric converter 101 serving as a large pixel and the second photoelectric converter 102 serving as a small pixel are formed adjacent to each other, even a small amount of light leaking could have a major impact on image quality.

As described with reference to FIG. 4, in the pixel 100 to which the present technology is applied, the light-blocking walls 151 are not formed in a region where the light-blocking walls 151 may intersect. The light-blocking wall 151 is not formed in a region where the light-blocking walls 151 may intersect, that is, the region corresponding to the region P in the example described with reference to FIG.

5. Therefore, it is possible to eliminate a region where a portion is dug deeply due to the micro-loading effect and to enable trenches to be processed to a uniform depth.

According to the present technology, the depth of the trench can be made uniform, and the depth can be, for example, set to depth L1 in the example shown in FIG. 5B. All of the light-blocking walls 151-1 to 151-28 shown in FIG. 4 can be formed to depth L1, for example, the light-blocking walls 151 can be formed to a uniform depth without forming some light-blocking walls 151 to a large depth.

According to the present technology, it is possible to provide the light-blocking walls 151 with a uniform depth, reduce the leakage of light into adjacent pixels, reduce color mixture, and improve image quality.

### Second Embodiment

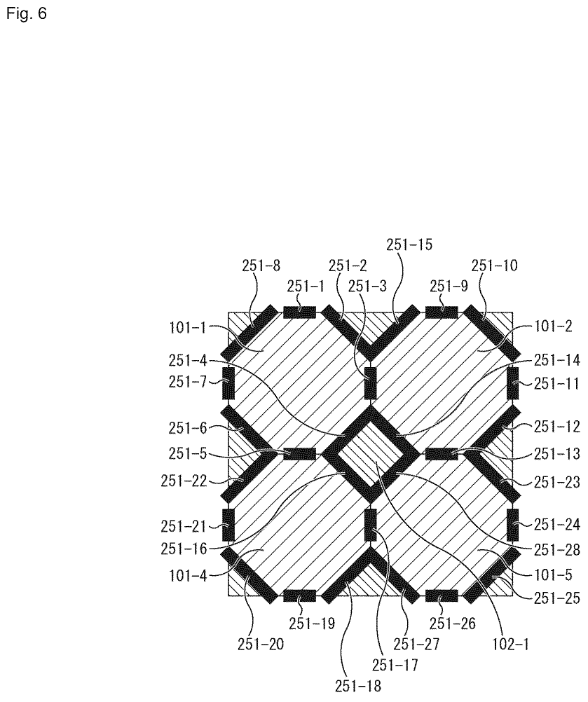

FIG. 6 is a diagram for explaining the configuration of the unit pixel 100 in the second embodiment. FIG. 6 shows 2×2 first photoelectric converters 101, similar to the first embodiment shown in FIG. 4.

A light-blocking wall 251-1 is formed on the upper side of the first photoelectric converter 101-1 located at the upper left in the figure. A light-blocking wall 251-2 is formed on the upper right oblique side of the first photoelectric converter 101-1. A light-blocking wall 251-3 is formed on the right side of the first photoelectric converter 101-1. A light-blocking wall 251-4 is formed on the lower right oblique side of the first photoelectric converter 101-1.

A light-blocking wall 251-5 is formed on the lower side of the first photoelectric converter 101-1. A light-blocking wall 251-6 is formed on the lower left oblique side of the first photoelectric converter 101-1. A light-blocking wall 251-7 is formed on the left side of the first photoelectric converter 101-1. A light-blocking wall 251-8 is formed on the upper left oblique side of the first photoelectric converter 101-1.

The light-blocking walls 251-1 to 251-8 provided in the first photoelectric converter 101-1 are provided in a spaced-apart shape.

A light-blocking wall 251-9 is formed on the upper side of the first photoelectric converter 101-2 located at the upper right in the figure. A light-blocking wall 251-10 is formed on the upper right oblique side of the first photoelectric converter 101-2. A light-blocking wall 251-11 is formed on the right side of the first photoelectric converter 101-2. A light-blocking wall 251-12 is formed on the lower right oblique side of the first photoelectric converter 101-2.

A light-blocking wall 251-13 is formed on the lower side of the first photoelectric converter 101-2. A light-blocking wall 251-14 is formed on the lower left oblique side of the first photoelectric converter 101-2. A light-blocking wall 251-3 is formed on the left side of the first photoelectric converter 101-2 (the side between the first photoelectric converter 101-2 and the first photoelectric converter 101-1). A light-blocking wall 251-15 is formed on the upper left oblique side of the first photoelectric converter 101-2.

The light-blocking walls 251-3, 251-9 to 251-15 provided in the first photoelectric converter 101-2 are provided in a spaced-apart shape.

A light-blocking wall 251-5 is formed on the upper side of the first photoelectric converter 101-4 located at the lower left in the figure (the side between the first photoelectric converter 101-4 and the first photoelectric converter 101-1). A light-blocking wall 251-16 is formed on the upper right oblique side of the first photoelectric converter 101-4. A light-blocking wall 251-17 is formed on the right side of the first photoelectric converter 101-4. A light-blocking wall 251-18 is formed on the lower right oblique side of the first photoelectric converter 101-4.

A light-blocking wall 251-19 is formed on the lower side of the first photoelectric converter 101-4. A light-blocking wall 251-20 is formed on the lower left oblique side of the first photoelectric converter 101-4. A light-blocking wall 251-21 is formed on the left side of the first photoelectric converter 101-4. A light-blocking wall 251-22 is formed on the upper left oblique side of the first photoelectric converter 101-4.

The light-blocking walls 251-5, 251-16 to 251-22 provided in the first photoelectric converter 101-4 are provided in a spaced-apart shape.

A light-blocking wall 251-13 is formed on the upper side of the first photoelectric converter 101-5 located at the lower right in the figure (the side between the first photoelectric converter 101-5 and the first photoelectric converter 101-2). A light-blocking wall 251-23 is formed on the upper right oblique side of the first photoelectric converter 101-5. A light-blocking wall 251-24 is formed on the right side of the first photoelectric converter 101-5. A light-blocking wall 251-25 is formed on the lower right oblique side of the first photoelectric converter 101-5.

A light-blocking wall 251-26 is formed on the lower side of the first photoelectric converter 101-5. A light-blocking wall 251-27 is formed on the lower left oblique side of the first photoelectric converter 101-5. A light-blocking wall 251-17 is formed on the left side of the first photoelectric converter 101-5 (the side between the first photoelectric converter 101-5 and the first photoelectric converter 101-4). A light-blocking wall 251-28 is formed on the upper left oblique side of the first photoelectric converter 101-5.

The light-blocking walls 251-13, 251-17, 251-23 to 251-28 provided in the first photoelectric converter 101-5 are provided in a spaced-apart shape.

A light-blocking wall 251 is provided on each side of the first photoelectric converter 101, and a region that is not in contact with adjacent light-blocking walls 251 is provided at both ends of the light-blocking wall 251 provided on each side. As a result, as shown in FIG. 6, the light-blocking wall 251 has a configuration in which long light-blocking walls 251 and short light-blocking walls 251 are mixed.

Note that a configuration in which short light-blocking walls 251 are not formed may also be adopted.

A light-blocking wall 251-4 is formed between the upper left side of the second photoelectric converter 102-1 and the lower right oblique side of the first photoelectric converter 101-1. A light-blocking wall 251-14 is formed between the upper right side of the second photoelectric converter 102-1 and the lower left oblique side of the first photoelectric converter 101-2.

A light-blocking wall 251-28 is formed between the lower right side of the second photoelectric converter 102-1 and the upper left oblique side of the first photoelectric converter 101-5. A light-blocking wall 251-16 is formed between the lower left side of the second photoelectric converter 102-1 and the upper right oblique side of the first photoelectric converter 101-4.

The light-blocking wall 251 surrounding the second photoelectric converter 102-1 corresponding to a small pixel is formed in a continuous shape without any spaced-apart region. That is, in the example shown in FIG. 6, the light-blocking wall 251-4, the light-blocking wall 251-14, the light-blocking wall 251-28, and the light-blocking wall 251-16 are formed in a continuous shape without any spaced-apart region.

In the second embodiment, the second photoelectric converter 102 is surrounded by a light-blocking wall 252. By surrounding the second photoelectric converter 102, which serves as a small pixel, with the light-blocking wall 251, it is possible to prevent light from leaking from the first photoelectric converter 101, which serves as a large pixel.

The light-blocking walls 252 surrounding the first photoelectric converter 101 are formed with a spaced-apart region so that the light-blocking walls 252 do not intersect with each other. Therefore, the light-blocking walls 252 can be formed with a uniform depth, and leakage of light into adjacent pixels can be reduced.

According to the present technology, it is possible to provide the light-blocking walls 251 with a uniform depth and reduce the leakage of light into adjacent pixels. Even in the case of a configuration in which a small pixel and a large pixel are adjacent to each other, it is possible to reduce the leakage of light to the adjacent pixels, reduce color mixture, and improve image quality.

### Third Embodiment

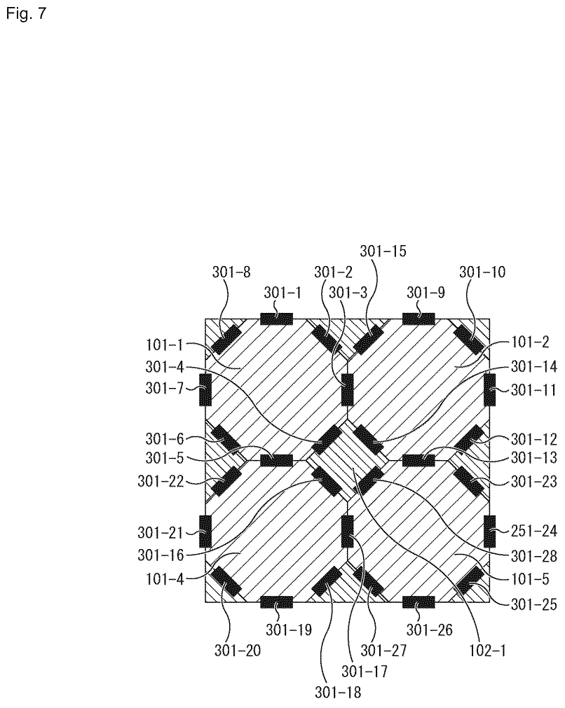

FIG. 7 is a diagram for explaining the configuration of the unit pixel 100 in the third embodiment. FIG. 7 shows 2×2 first photoelectric converters 101, similar to the first embodiment shown in FIG. 4.

A light-blocking wall 301-1 is formed on the upper side of the first photoelectric converter 101-1 located at the upper left in the figure. A light-blocking wall 301-2 is formed on the upper right oblique side of the first photoelectric converter 101-1. A light-blocking wall 301-3 is formed on the right side of the first photoelectric converter 101-1. A light-blocking wall 301-4 is formed on the lower right oblique side of the first photoelectric converter 101-1.

A light-blocking wall 301-5 is formed on the lower side of the first photoelectric converter 101-1. A light-blocking wall 301-6 is formed on the lower left oblique side of the first photoelectric converter 101-1. A light-blocking wall 301-7 is formed on the left side of the first photoelectric converter 101-1. A light-blocking wall 301-8 is formed on the upper left oblique side of the first photoelectric converter 101-1.

The light-blocking walls 301-1 to 301-8 provided in the first photoelectric converter 101-1 are provided in a spaced-apart shape.

A light-blocking wall 301-9 is formed on the upper side of the first photoelectric converter 101-2 located at the upper right in the figure. A light-blocking wall 301-10 is formed on the upper right oblique side of the first photoelectric converter 101-2. A light-blocking wall 301-11 is formed on the right side of the first photoelectric converter 101-2. A light-blocking wall 301-12 is formed on the lower right oblique side of the first photoelectric converter 101-2.

A light-blocking wall 301-13 is formed on the lower side of the first photoelectric converter 101-2. A light-blocking wall 301-14 is formed on the lower left oblique side of the first photoelectric converter 101-2. A light-blocking wall 301-3 is formed on the left side of the first photoelectric converter 101-2 (the side between the first photoelectric converter 101-2 and the first photoelectric converter 101-1). A light-blocking wall 301-15 is formed on the upper left oblique side of the first photoelectric converter 101-2.

The light-blocking walls 301-3, 301-9 to 301-15 provided in the first photoelectric converter 101-2 are provided in a spaced-apart shape.

A light-blocking wall 301-5 is formed on the upper side of the first photoelectric converter 101-4 located at the lower left in the figure (the side between the first photoelectric converter 101-4 and the first photoelectric converter 101-1). A light-blocking wall 301-16 is formed on the upper right oblique side of the first photoelectric converter 101-4. A light-blocking wall 301-17 is formed on the right side of the first photoelectric converter 101-4. A light-blocking wall 301-18 is formed on the lower right oblique side of the first photoelectric converter 101-4.

A light-blocking wall 301-19 is formed on the lower side of the first photoelectric converter 101-4. A light-blocking wall 301-20 is formed on the lower left oblique side of the first photoelectric converter 101-4. A light-blocking wall 301-21 is formed on the left side of the first photoelectric converter 101-4. A light-blocking wall 301-22 is formed on the upper left oblique side of the first photoelectric converter 101-4.

The light-blocking walls 301-5, 301-16 to 301-22 provided in the first photoelectric converter 101-4 are provided in a spaced-apart shape.

A light-blocking wall 301-13 is formed on the upper side of the first photoelectric converter 101-5 located at the lower right in the figure (the side between the first photoelectric converter 101-5 and the first photoelectric converter 101-2). A light-blocking wall 301-23 is formed on the upper right oblique side of the first photoelectric converter 101-5. A light-blocking wall 301-24 is formed on the right side of the first photoelectric converter 101-5. A light-blocking wall 301-25 is formed on the lower right oblique side of the first photoelectric converter 101-5.

A light-blocking wall 301-26 is formed on the lower side of the first photoelectric converter 101-5. A light-blocking wall 301-27 is formed on the lower left oblique side of the first photoelectric converter 101-5. A light-blocking wall 301-17 is formed on the left side of the first photoelectric converter 101-5 (the side between the first photoelectric converter 101-5 and the first photoelectric converter 101-4). A light-blocking wall 301-28 is formed on the upper left oblique side of the first photoelectric converter 101-5.

The light-blocking walls 301-13, 301-17, 301-23 to 301-28 provided in the first photoelectric converter 101-5 are provided in a spaced-apart shape.

A light-blocking wall 301 is provided on each side of the first photoelectric converter 101, and a region that is not in contact with the adjacent light-blocking wall 301 is provided at both ends of the light-blocking wall 301 provided on each side. As a result, as shown in FIG. 7, the light-blocking wall 301 has a configuration in which light-blocking walls 301 having substantially the same length are arranged on each side.

A light-blocking wall 301-4 is formed between the upper left side of the second photoelectric converter 102-1 and the lower right oblique side of the first photoelectric converter 101-1. A light-blocking wall 301-14 is formed between the upper right side of the second photoelectric converter 102-1 and the lower left oblique side of the first photoelectric converter 101-2.

A light-blocking wall 301-28 is formed between the lower right side of the second photoelectric converter 102-1 and the upper left oblique side of the first photoelectric converter 101-5. A light-blocking wall 301-16 is formed between the lower left side of the second photoelectric converter 102-1 and the upper right oblique side of the first photoelectric converter 101-4.

Similarly to the light-blocking wall 301 surrounding the first photoelectric converter 101, the light-blocking wall 301 surrounding the second photoelectric converter 102-1 corresponding to a small pixel is also formed with a spaced-apart region. That is, in the example shown in FIG. 7, the light-blocking wall 301-4, the light-blocking wall 301-14, the light-blocking wall 301-28, and the light-blocking wall 301-16 are formed in a spaced-apart shape.

In the third embodiment, the light-blocking walls 301 formed in the first photoelectric converter 101 and the second photoelectric converter 102 are formed without any intersecting region. In other words, the light-blocking walls 301 formed on each side of the first photoelectric converter 101 and each side of the second photoelectric converter 102 are configured to have a region at both ends where a light-blocking wall is not formed.

Since there is no region where the light-blocking walls intersect, there is no region subject to the micro-loading effect, and the depth of the light-blocking walls 301 can be made uniform, making it possible to reduce the leakage of light into adjacent pixels.

According to the present technology, it is possible to provide the light-blocking walls 301 with a uniform depth and reduce the leakage of light into adjacent pixels. Even in the case of a configuration in which a small pixel and a large pixel are adjacent to each other, it is possible to reduce the leakage of light to the adjacent pixels, reduce color mixture, and improve image quality.

### Fourth Embodiment

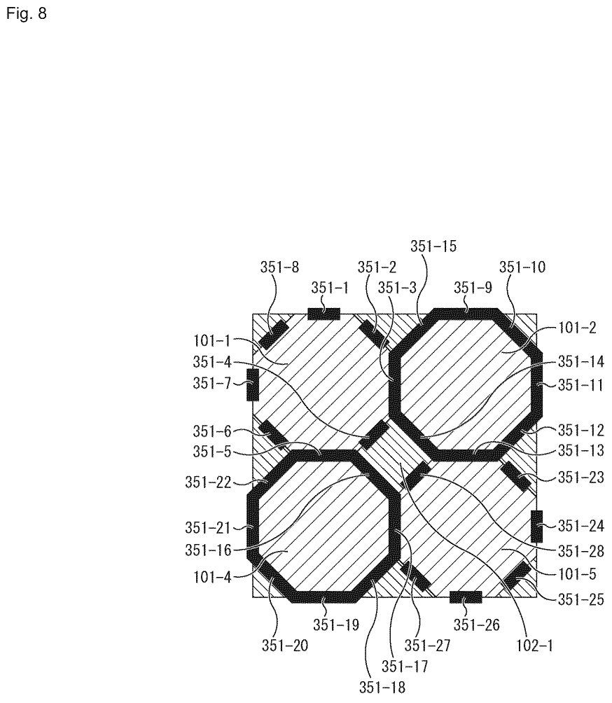

FIG. 8 is a diagram for explaining the configuration of the unit pixel 100 in the fourth embodiment. FIG. 8 shows 2x2 first photoelectric converters 101, similar to the first embodiment shown in FIG. 4.

A light-blocking wall 351-1 is formed on the upper side of the first photoelectric converter 101-1 located at the upper left in the figure. A light-blocking wall 351-2 is formed on the upper right oblique side of the first photoelectric converter 101-1.

A light-blocking wall 351-3 is formed on the right side of the first photoelectric converter 101-1. A light-blocking wall 351-4 is formed on the lower right oblique side of the first photoelectric converter 101-1.

A light-blocking wall 351-5 is formed on the lower side of the first photoelectric converter 101-1. A light-blocking wall 351-6 is formed on the lower left oblique side of the first photoelectric converter 101-1. A light-blocking wall 351-7 is formed on the left side of the first photoelectric converter 101-1. A light-blocking wall 351-8 is formed on the upper left oblique side of the first photoelectric converter 101-1.

The light-blocking walls 351-1 to 351-8 provided in the first photoelectric converter 101-1 are provided in a spaced-apart shape.

A light-blocking wall 351-9 is formed on the upper side of the first photoelectric converter 101-2 located at the upper right in the figure. A light-blocking wall 351-10 is formed on the upper right oblique side of the first photoelectric converter 101-2. A light-blocking wall 351-11 is formed on the right side of the first photoelectric converter 101-2. A light-blocking wall 351-12 is formed on the lower right oblique side of the first photoelectric converter 101-2.

A light-blocking wall 351-13 is formed on the lower side of the first photoelectric converter 101-2. A light-blocking wall 351-14 is formed on the lower left oblique side of the first photoelectric converter 101-2. A light-blocking wall 351-3 is formed on the left side of the first photoelectric converter 101-2 (the side between the first photoelectric converter 101-2 and the first photoelectric converter 101-1). A light-blocking wall 351-15 is formed on the upper left oblique side of the first photoelectric converter 101-2.

The light-blocking walls 351-3, 351-9 to 351-15 provided in the first photoelectric converter 101-2 have no spaced-apart region and are provided in a continuous shape.

A light-blocking wall 351-5 is formed on the upper side of the first photoelectric converter 101-4 located at the lower left in the figure (the side between the first photoelectric converter 101-4 and the first photoelectric converter 101-1). A light-blocking wall 351-16 is formed on the upper right oblique side of the first photoelectric converter 101-4. A light-blocking wall 351-17 is formed on the right side of the first photoelectric converter 101-4. A light-blocking wall 351-18 is formed on the lower right oblique side of the first photoelectric converter 101-4.

A light-blocking wall 351-19 is formed on the lower side of the first photoelectric converter 101-4. A light-blocking wall 351-20 is formed on the lower left oblique side of the first photoelectric converter 101-4. A light-blocking wall 351-21 is formed on the left side of the first photoelectric converter 101-4. A light-blocking wall 351-22 is formed on the upper left oblique side of the first photoelectric converter 101-4.

The light-blocking walls 351-5, 351-16 to 351-22 provided in the first photoelectric converter 101-4 have no spaced-apart region and are provided in a continuous shape.

A light-blocking wall 351-13 is formed on the upper side of the first photoelectric converter 101-5 located at the lower right in the figure (the side between the first photoelectric converter 101-5 and the first photoelectric converter 101-2). A light-blocking wall 351-23 is formed on the upper right oblique side of the first photoelectric converter 101-5. A light-blocking wall 351-24 is formed on the right side of the first photoelectric converter 101-5. A light-blocking wall 351-25 is formed on the lower right oblique side of the first photoelectric converter 101-5.

A light-blocking wall 351-26 is formed on the lower side of the first photoelectric converter 101-5. A light-blocking wall 351-27 is formed on the lower left oblique side of the first photoelectric converter 101-5. A light-blocking wall 351-17 is formed on the left side of the first photoelectric converter 101-5 (the side between the first photoelectric converter 101-5 and the first photoelectric converter 101-4). A light-blocking wall 351-28 is formed on the upper left oblique side of the first photoelectric converter 101-5.

The light-blocking walls 351-13, 351-17, 351-23 to 351-28 provided in the first photoelectric converter 101-5 are provided in a spaced-apart shape.

A light-blocking wall 351-4 is formed between the upper left side of the second photoelectric converter 102-1 and the lower right oblique side of the first photoelectric converter 101-1. A light-blocking wall 351-14 is formed between the upper right side of the second photoelectric converter 102-1 and the lower left oblique side of the first photoelectric converter 101-2.

A light-blocking wall 351-28 is formed between the lower right side of the second photoelectric converter 102-1 and the upper left oblique side of the first photoelectric converter 101-5. A light-blocking wall 351-16 is formed between the lower left side of the second photoelectric converter 102-1 and the upper right oblique side of the first photoelectric converter 101-4.

The light-blocking wall 351-4, the light-blocking wall 351-14, the light-blocking wall 351-28, and the light-blocking wall 351-16 surrounding the second photoelectric converter 102-2 corresponding to a small pixel each are provided in a spaced-apart shape.

In the fourth embodiment, the first photoelectric converters 101 are classified into pixels in which light-blocking walls 351 are provided in a spaced-apart shape (hereinafter referred to as spaced-apart pixels) and pixels in which light-blocking walls 351 are provided in a continuous shape (hereinafter referred to as continuous pixels). In the example shown in FIG. 8, the first photoelectric converter 101-1 and the first photoelectric converter 101-5 are spaced-apart pixels, and the first photoelectric converter 101-2 and the first photoelectric converter 101-4 are continuous pixels.

As shown in FIG. 8, the spaced-apart pixels and the continuous pixels are arranged alternately. In the example shown in FIG. 8, the pixel including the first photoelectric converter 101-1 is a spaced-apart pixel, and the pixel including the first photoelectric converter 101-2 located next to it is a continuous pixel. Although not shown in FIG. 8, a pixel including the first photoelectric converter 101-3 (FIG. 3) located next to the first photoelectric converter 101-2, which is a continuous pixel, corresponds to a spaced-apart pixel.

When viewed in the horizontal direction, spaced-apart pixels and continuous pixels are arranged alternately. Similarly, when viewed in the vertical direction, spaced-apart pixels and continuous pixels are alternately arranged. That is, the spaced- apart pixels and the continuous pixels are arranged alternately in each of the vertical and horizontal directions.

Since the continuous pixels are surrounded by the light-blocking wall 351, it is possible to prevent light from leaking from the continuous pixels to spaced-apart pixels. Furthermore, the light-blocking walls 351 provided in the continuous pixels can prevent light from leaking from the spaced-apart pixels to the continuous pixels. That is, it is possible to prevent light from leaking from the first photoelectric converter 101 to the adjacent first photoelectric converter 101.

In the fourth embodiment, the light-blocking walls 351 formed in the first photoelectric converter 101 and the second photoelectric converter 102 are formed in a state where there is no intersecting region or a place where at least three light-blocking walls 351 intersect. Since there are fewer intersecting regions, there are fewer regions that are subject to the micro-loading effect, and the depth of the light-blocking wall 351 can be made uniform, making it possible to reduce the leakage of light into adjacent pixels.

According to the present technology, it is possible to provide the light-blocking walls 351 with a uniform depth and reduce the leakage of light into adjacent pixels. Even in the case of a configuration in which a small pixel and a large pixel are adjacent to each other, it is possible to reduce the leakage of light to the adjacent pixels, reduce color mixture, and improve image quality.

### Fifth Embodiment

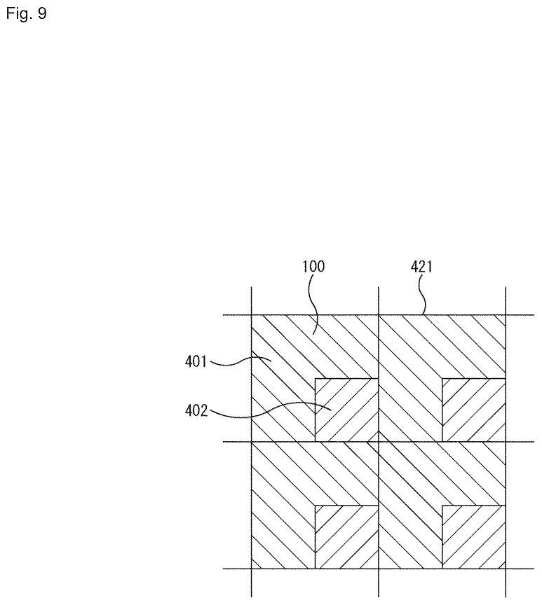

FIG. 9 is a diagram for explaining the configuration of the unit pixel 100 in the fifth embodiment. Since the unit pixel 100 in the fifth embodiment has a different configuration from the unit pixel 100 in the first to fourth embodiments described above, the configuration of the unit pixel 100 in the fifth embodiment will be explained with reference to FIG. 9.

FIG. 9 is a diagram showing an example of the planar configuration of the unit pixels 100 arranged in the pixel array unit 11. FIG. 9 illustrates four (2×2) unit pixels 100 arranged in the pixel array unit 11.

The unit pixel 100 includes a first photoelectric converter 401 formed in an L-shape (corresponding to the first photoelectric converter 101 in the first to fourth embodiments) and a second photoelectric converter 402 formed in a rectangle shape (corresponding to the second photoelectric converter 102 in the first to fourth embodiments). The combined shape of the first photoelectric converter 401 and the second photoelectric converter 402, in other words, the shape of the unit pixel 100 is formed in a square shape (rectangle in FIG. 9).

In the following explanation, it will be described as an L-shape, but an L-shape is a shape that is divided into a vertical line and a horizontal line and the lengths of the vertical line and horizontal line are different. In the present embodiment, the L-shape also includes a shape in which the lengths of the vertical line and the horizontal line are the same. Furthermore, the L-shape refers to the shape of “L”, and includes shapes when L is rotated by 90 degrees, 180 degrees, or 270 degrees.

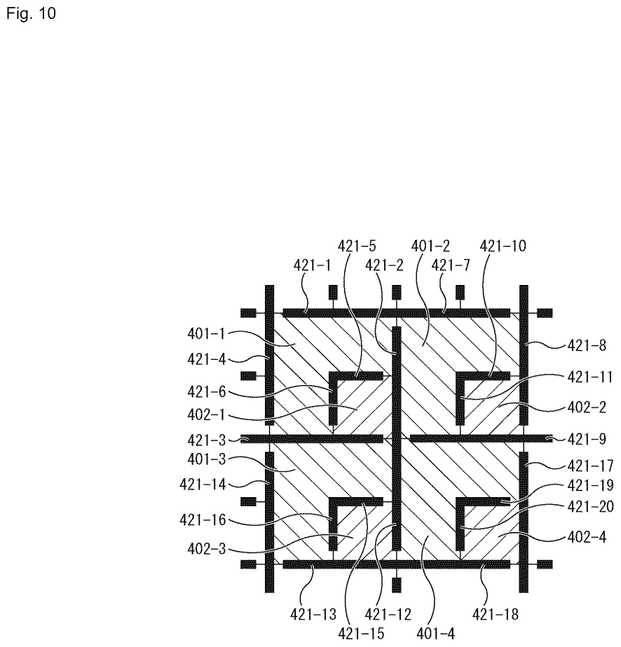

In the pixel array unit 11, unit pixels 100 each including a first photoelectric converter 401 and a second photoelectric converter 402 are arranged in a matrix. The unit pixels 100 are separated by a light-blocking wall 421 (described later with reference to FIG. 10). A light-blocking wall 421 is also formed between the first photoelectric converter 401 and the second photoelectric converter 402, and the first photoelectric converter 401 and the second photoelectric converter 402 are separated by the light-blocking wall 421.

In the first photoelectric converter 401, for example, N-type impurity regions are formed in a continuous shape in a silicon substrate, forming one photoelectric converter.

The first photoelectric converter 401 is formed in an L-shape and is formed as a region having a light-receiving area three times that of the second photoelectric converter 402. The unit pixel 100 includes a large pixel having a light-receiving area three times that of the second photoelectric converter 402 and a small pixel having a light-receiving area one-third that of the first photoelectric converter 401. When viewed from the unit pixel 100, a 3/4 region of the unit pixel 100 is the first photoelectric converter 401 (large pixel), and a 1/4 region is the second photoelectric converter 402 (small pixel).

By configuring the first photoelectric converter 401 in an L-shape and arranging the second photoelectric converter 402 in a recessed region of the L-shaped first photoelectric converter 401, the first photoelectric converter 401 and the second photoelectric converter 402 can be efficiently arranged without creating an unnecessary gap between the first photoelectric converter 401 and the second photoelectric converter 402.

FIG. 10 is a diagram for explaining the configuration of the light-blocking wall 421 in the fifth embodiment.

A light-blocking wall 421-1 is formed on the upper side of the first photoelectric converter 401-1 located at the upper left in the figure. A light-blocking wall 421-2 is formed on the right side of the first photoelectric converter 401-1. A light-blocking wall 421-3 is formed on the lower side of the first photoelectric converter 401-1. A light-blocking wall 421-4 is formed on the left side of the first photoelectric converter 401-1.

The light-blocking walls 421-1 to 421-4 provided in the first photoelectric converter 401-1 are provided in a spaced-apart shape.

A light-blocking wall 421-5 is formed on the upper side of the second photoelectric converter 402-1 that forms the unit pixel 100 together with the first photoelectric converter 401-1. A light-blocking wall 421-2 is formed on the right side of the second photoelectric converter 402-1. A light-blocking wall 421-3 is formed on the lower side of the second photoelectric converter 402-1. A light-blocking wall 421-6 is formed on the left side of the second photoelectric converter 402-1.

The light-blocking wall 421-5 provided on the upper side of the second photoelectric converter 402-1 and the light-blocking wall 421-6 provided on the left side are provided in a continuous shape. The light-blocking wall 421-5 provided on the upper side of the second photoelectric converter 402-1 and the light-blocking wall 421-2 provided on the right side are provided in a spaced-apart shape. The light-blocking wall 421-6 provided on the left side of the second photoelectric converter 402-1 and the light-blocking wall 421-3 provided on the lower side are provided in a spaced-apart shape.

A light-blocking wall 421-7 is formed on the upper side of the first photoelectric converter 401-2 located at the upper right in the figure. A light-blocking wall 421-8 is formed on the right side of the first photoelectric converter 401-2. A light-blocking wall 421-9 is formed on the lower side of the first photoelectric converter 401-2. A light-blocking wall 421-2 is formed on the left side of the first photoelectric converter 401-2 (the side between the first photoelectric converter 401-2 and the first photoelectric converter 401-1).

The light-blocking walls 421-2, 421-7 to 421-9 provided in the first photoelectric converter 401-2 are provided in a spaced-apart shape. The light-blocking wall 421-1 formed on the upper side of the first photoelectric converter 101-1 and the light-blocking wall 421-7 formed on the upper side of the first photoelectric converter 101-2 are formed in a continuous linear shape.

A light-blocking wall 421-10 is formed on the upper side of the second photoelectric converter 402-2 that forms the unit pixel 100 together with the first photoelectric converter 401-2. A light-blocking wall 421-8 is formed on the right side of the second photoelectric converter 402-2. A light-blocking wall 421-9 is formed on the lower side of the second photoelectric converter 402-2. A light-blocking wall 421-11 is formed on the left side of the second photoelectric converter 402-2.

The light-blocking wall 421-10 provided on the upper side of the second photoelectric converter 402-2 and the light-blocking wall 421-11 provided on the left side are provided in a continuous shape. The light-blocking wall 421-10 provided on the upper side of the second photoelectric converter 402-2 and the light-blocking wall 421-8 provided on the right side are provided in a spaced-apart shape. The light-blocking wall 421-11 provided on the left side of the second photoelectric converter 402-2 and the light-blocking wall 421-9 provided on the lower side are provided in a spaced-apart shape.

A light-blocking wall 421-3 is formed on the upper side of the first photoelectric converter 401-3 located at the lower left in the figure. A light-blocking wall 421-12 is formed on the right side of the first photoelectric converter 401-3. A light-blocking wall 421-13 is formed on the lower side of the first photoelectric converter 401-3. A light-blocking wall 421-14 is formed on the left side of the first photoelectric converter 401-3.

The light-blocking walls 421-3, 421-12 to 421-14 provided in the first photoelectric converter 401-3 are provided in a spaced-apart shape. The light-blocking wall 421-2 formed on the right side of the first photoelectric converter 101-1 and the light-blocking wall 421-12 formed on the right side of the first photoelectric converter 101-3 are formed in a continuous linear shape.

A light-blocking wall 421-15 is formed on the upper side of the second photoelectric converter 402-3 that forms the unit pixel 100 together with the first photoelectric converter 401-3. A light-blocking wall 421-12 is formed on the right side of the second photoelectric converter 402-3. A light-blocking wall 421-13 is formed on the lower side of the second photoelectric converter 402-3. A light-blocking wall 421-16 is formed on the left side of the second photoelectric converter 402-3.

The light-blocking wall 421-15 provided on the upper side of the second photoelectric converter 402-3 and the light-blocking wall 421-16 provided on the left side are provided in a continuous shape. The light-blocking wall 421-15 provided on the upper side of the second photoelectric converter 402-3 and the light-blocking wall 421-12 provided on the right side are provided in a spaced-apart shape. The light-blocking wall 421-16 provided on the left side of the second photoelectric converter 402-3 and the light-blocking wall 421-13 provided on the lower side are provided in a spaced-apart shape.

A light-blocking wall 421-9 is formed on the upper side of the first photoelectric converter 401-4 located at the lower right in the figure (the side between the first photoelectric converter 401-4 and the first photoelectric converter 401-2). A light-blocking wall 421-17 is formed on the right side of the first photoelectric converter 401-4. A light-blocking wall 421-18 is formed on the lower side of the first photoelectric converter 401-4. A light-blocking wall 421-12 is formed on the left side of the first photoelectric converter 401-4 (the side between the first photoelectric converter 401-4 and the first photoelectric converter 401-3).

The light-blocking walls 421-9, 421-12, 421-17, and 421-18 provided in the first photoelectric converter 401-4 are provided in a spaced-apart shape. The light-blocking wall 421-13 formed on the lower side of the first photoelectric converter 101-3 and the light-blocking wall 421-18 formed on the lower side of the first photoelectric converter 101-4 are formed in a continuous linear shape.

A light-blocking wall 421-19 is formed on the upper side of the second photoelectric converter 402-4 that forms the unit pixel 100 together with the first photoelectric converter 401-4. A light-blocking wall 421-17 is formed on the right side of the second photoelectric converter 402-4. A light-blocking wall 421-18 is formed on the lower side of the second photoelectric converter 402-4. A light-blocking wall 421-20 is formed on the left side of the second photoelectric converter 402-4.

The light-blocking wall 421-19 provided on the upper side of the second photoelectric converter 402-4 and the light-blocking wall 421-20 provided on the left side are provided in a continuous shape. The light-blocking wall 421-19 provided on the upper side of the second photoelectric converter 402-4 and the light-blocking wall 421-17 provided on the right side are provided in a spaced-apart shape. The light-blocking wall 421-20 provided on the left side of the second photoelectric converter 402-4 and the light-blocking wall 421-18 provided on the lower side are provided in a spaced-apart shape.

The light-blocking walls 421 provided on each side of the first photoelectric converter 401 are configured such that one end is a spaced-apart region and the other end is connected to another light-blocking wall 421. For example, a spaced-apart region is provided at one end of the light-blocking wall 421-1, and a light-blocking wall 421-7 is connected to the other end.

In the fifth embodiment, the L-shaped first photoelectric converter 401 corresponding to a large pixel is formed so that there is no region where the light-blocking walls 421 intersect. A light-blocking wall 421 is also provided between the second photoelectric converter 402 corresponding to a small pixel and the first photoelectric converter 401. Therefore, the light-blocking wall 421 can prevent light from leaking from the first photoelectric converter 401 to the second photoelectric converter 402.

The light-blocking walls 421 are formed in such a manner that there are spaced-apart regions so that the light-blocking walls 421 do not intersect. Therefore, the light-blocking walls 421 can be formed with a uniform depth, and leakage of light into adjacent pixels can be reduced.

According to the present technology, it is possible to provide the light-blocking walls 421 with a uniform depth and reduce the leakage of light into adjacent pixels. Even in the case of a configuration in which a small pixel and a large pixel are adjacent to each other, it is possible to reduce the leakage of light to the adjacent pixels, reduce color mixture, and improve image quality.

### Sixth Embodiment

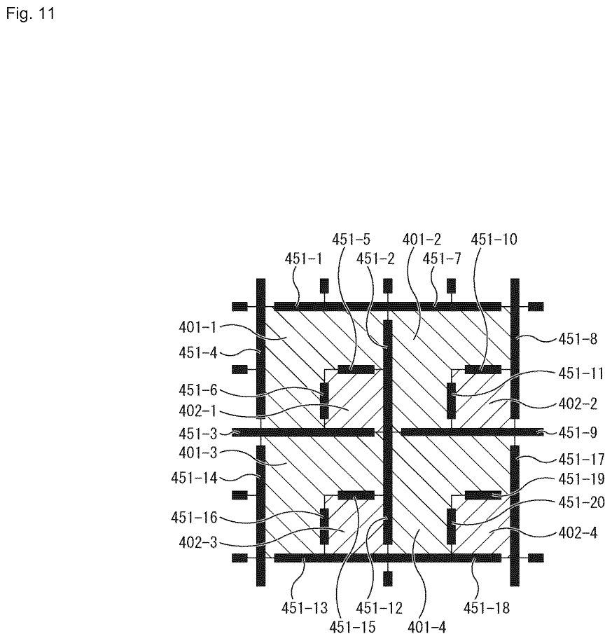

FIG. 11 is a diagram for explaining the configuration of the light-blocking wall 451 provided in the unit pixel 100 in the sixth embodiment.

Similarly to the unit pixel 100 in the fifth embodiment shown in FIG. 10, the unit pixel 100 in the sixth embodiment shown in FIG. 11 includes an L-shaped first photoelectric converter 401 and a second photoelectric converter 402. The light-blocking wall 451 formed in the first photoelectric converter 401 is basically provided in the same arrangement as the light-blocking wall 421 formed in the first photoelectric converter 401 shown in FIG. 10, and thus, the explanation will be omitted as appropriate.

The first photoelectric converter 401-1 is provided with a light-blocking wall 451-1, a light-blocking wall 451-2, a light-blocking wall 451-3, and a light-blocking wall 451-4, which are provided in a spaced-apart state. The second photoelectric converter 402-1 is provided with a light-blocking wall 451-2, a light-blocking wall 451-3, a light-blocking wall 451-5, and a light-blocking wall 451-6, which are provided in a spaced-apart state.

The first photoelectric converter 401-2 is provided with a light-blocking wall 451-2, a light-blocking wall 451-7, a light-blocking wall 451-8, and a light-blocking wall 451-9, which are provided in a spaced-apart state. The second photoelectric converter 402-2 is provided with a light-blocking wall 451-8, a light-blocking wall 451-9, a light-blocking wall 451-10, and a light-blocking wall 451-11, which are provided in a spaced-apart state.

The first photoelectric converter 401-3 is provided with a light-blocking wall 451-3, a light-blocking wall 451-12, a light-blocking wall 451-13, and a light-blocking wall 451-14, which are provided in a spaced-apart state. The second photoelectric converter 402-3 is provided with a light-blocking wall 451-12, a light-blocking wall 451-13, a light-blocking wall 451-15, and a light-blocking wall 451-16, which are provided in a spaced-apart state.

The first photoelectric converter 401-4 is provided with a light-blocking wall 451-9, a light-blocking wall 451-12, a light-blocking wall 451-17, and a light-blocking wall 451-18, which are provided in a spaced-apart state. The second photoelectric converter 402-4 is provided with a light-blocking wall 451-17, a light-blocking wall 451-18, a light-blocking wall 451-19, and a light-blocking wall 451-20, which are provided in a spaced-apart state.

The light-blocking wall 451 of the second photoelectric converter 402 in the sixth embodiment is formed in a shape without corners. That is, as described above, for example, referring to the second photoelectric converter 102-2, the second photoelectric converter 102-2 is provided with a light-blocking wall 451-2, a light-blocking wall 451-3, a light-blocking wall 451-5, and a light-blocking wall 451-6, which are provided in a spaced-apart state.

For comparison, referring again to the second photoelectric converter 102-2 shown in FIG. 10, the light-blocking wall 421-5 and the light-blocking wall 421-6 of the second photoelectric converter 102-2 shown in FIG. 10 are formed in a continuous shape with corners. In contrast to the second photoelectric converter 102-2 shown in FIG. 10, the light-blocking wall 451-5 and the light-blocking wall 451-6 of the second photoelectric converter 402-2 shown in FIG. 11 are not formed in a continuous shape but in a spaced-apart shape without corners.

The light-blocking walls 451 provided on two of the four sides constituting the second photoelectric converter 402 are configured to have a spaced-apart region at both ends. For example, the light-blocking wall 451-5 and the light-blocking wall 451-6 of the second photoelectric converter 402-1 each have a region at both ends where no light-blocking wall is formed.

According to the sixth embodiment, there are no regions where the light-blocking walls 451 intersect, in other words, there are no regions where a corner is created by the light-blocking walls 451, and the light-blocking walls 451 can be formed with a more uniform depth. Furthermore, it is possible to reduce the leakage of light into adjacent pixels.

According to the present technology, it is possible to provide the light-blocking walls 451 with a uniform depth and reduce the leakage of light into adjacent pixels. Even in the case of a configuration in which a small pixel and a large pixel are adjacent to each other, it is possible to reduce the leakage of light to the adjacent pixels, reduce color mixture, and improve image quality.

According to the present technology, by providing the region where the light-blocking walls intersect so as to be spaced apart, it is possible to suppress the phenomenon in which only the portions where the light-blocking walls intersect are dug deeply due to the micro-loading effect during trench processing for embedding the light-blocking walls. As a result, the light-blocking walls can be processed to a uniform depth, and even if light enters deep into the sensor, color mixture can be suppressed for even long-wavelength light that is difficult to convert into electricity, for example.

### Application to Electronic Apparatus

The present technology can be applied to a general electronic apparatus in which an imaging element is used in an imaging unit (a photoelectric converter), such as an imaging device such as a digital still camera or a video camera, a portable terminal device that has an imaging function, or a copy machine in which an imaging element is used in an image reading unit. The imaging element may be formed as a one-chip or may be formed as a module in which an imaging unit and a signal processor or an optical system are collectively packaged and which has an imaging function.

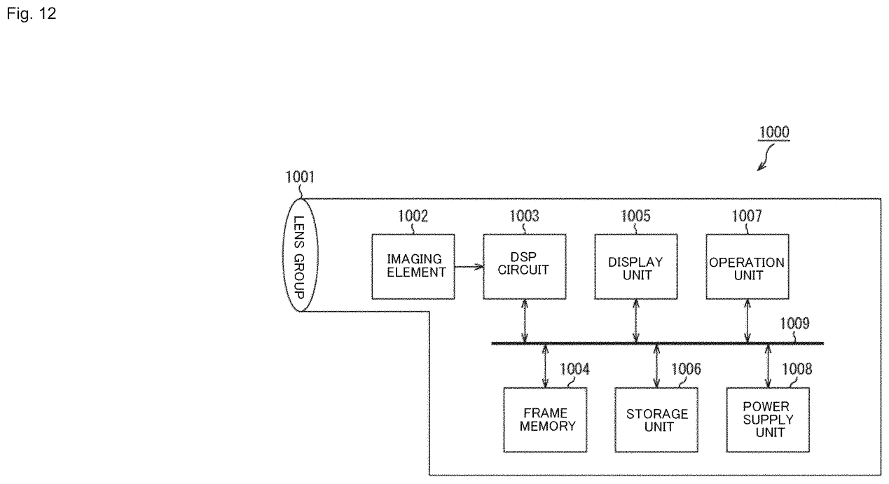

FIG. 12 is a block diagram showing an exemplary configuration of an imaging device which is an electronic apparatus to which the present technology is applied.

An imaging device 1000 in FIG. 12 includes an optical unit 1001 formed of a lens group, an imaging element (an imaging device) 1002 in which the configuration of the imaging device 10 in FIG. 1, and a digital signal processor (DSP) circuit 1003 which is a camera signal processing circuit. The imaging device 1000 also includes a frame memory 1004, a display unit 1005, a recording unit 1006, an operation unit 1007, and a power source unit 1008. The DSP circuit 1003, the frame memory 1004, the display unit 1005, the recording unit 1006, the operation unit 1007, and the power source unit 1008 are connected via a bus line 1009.

The optical unit 1001 captures incident light (image light) from a subject and forms an image on an imaging surface of the imaging element 1002. The imaging element 1002 converts an amount of incident light formed on the imaging surface by the optical unit 1001 into an electrical signal in units of pixels and outputs the electrical signal as a pixel signal. The imaging device 10 in FIG. 1 can be used as the imaging element 1002.

The display unit 1005 is configured as, for example, a thin display such as a liquid crystal display (LCD) or an organic electro luminescence (EL) display and displays a moving image or a still image captured by the imaging element 1002. The recording unit 1006 records a moving image or a still image captured by the imaging element 1002 in a recording medium such as a hard disk or a semiconductor memory.

The operation unit 1007 issues operation commands for various functions of the imaging device 1000 based on the operations of a user. The power source unit 1008 appropriately supplies various types of power serving as operation power sources of the DSP circuit 1003, the frame memory 1004, the display unit 1005, the recording unit 1006, and the operation unit 1007 to supply targets.

### Application to Mobile Object

The technology of the present disclosure (the present technology) can be applied to various products. For example, the technique according to the present disclosure may be realized as a device mounted on any type of moving body such as an automobile, an electric automobile, a hybrid electric automobile, a motorcycle, a bicycle, a personal mobility device, an airplane, a drone, a ship, a robot, or the like.

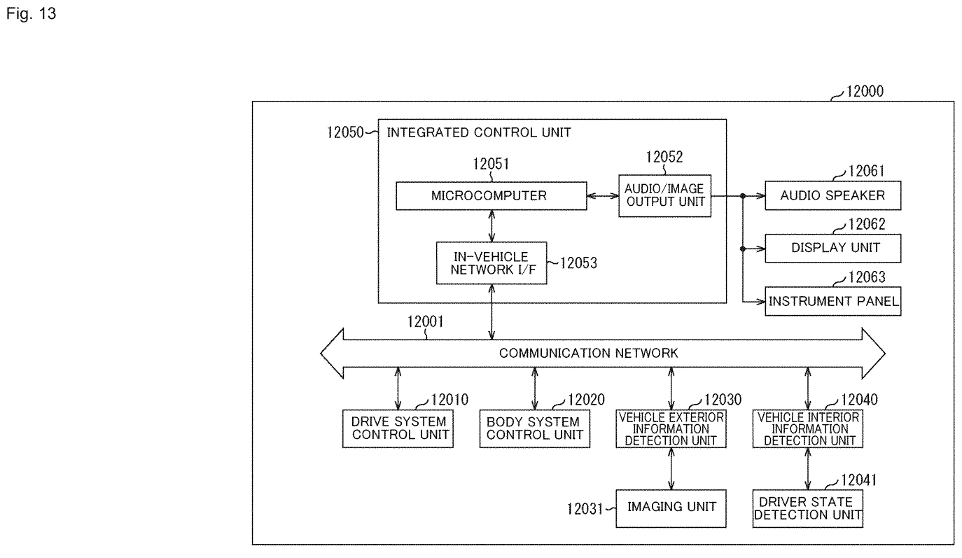

FIG. 13 is a block diagram showing a schematic configuration example of a vehicle control system, which is an example of a moving body control system to which the technique according to the present disclosure can be applied.

The vehicle control system 12000 includes a plurality of electronic controllers connected via a communication network 12001. In the example shown in FIG. 13, the vehicle control system 12000 includes a drive system control unit 12010, a body system control unit 12020, a vehicle exterior information detection unit 12030, a vehicle interior information detection unit 12040, and an integrated control unit 12050. As a functional configuration of the integrated control unit 12050, a microcomputer 12051, an audio/image output unit 12052, and an in-vehicle network I/F (interface) 12053 are shown.

The drive system control unit 12010 controls the operation of an apparatus related to a drive system of a vehicle according to various programs. For example, the drive system control unit 12010 serves as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls the operations of various devices mounted in the vehicle body according to various programs. For example, the body system control unit 12020 serves as a control device for a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receive the captured image. The vehicle exterior information detection unit 12030 may perform object detection processing or distance detection processing for people, cars, obstacles, signs, and letters on the road based on the received image.

The imaging unit 12031 is an optical sensor that receives light and outputs an electrical signal corresponding to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate the degree of fatigue or concentration of the driver or may determine whether or not the driver is dozing based on detection information input from the driver state detection unit 12041.

The microcomputer 12051 can calculate control target values for the driving force generation device, the steering mechanism, or the braking device based on information on the inside and outside of the vehicle, the information being acquired by the vehicle exterior information detection unit 12030 or the vehicle interior information detection unit 12040, and the microcomputer 12051 can output control commands to the drive system control unit 12010. For example, the microcomputer 12051 can perform cooperative control to implement the functions of an advanced driver assistance system (ADAS) including vehicle collision avoidance, impact mitigation, following traveling based on an inter-vehicle distance, vehicle speed maintenance driving, vehicle collision warning, and vehicle lane deviation warning.

Further, the microcomputer 12051 can perform cooperative control for automated driving or the like in which autonomous travel is performed without depending on the operations of the driver, by controlling the driving force generator, the steering mechanism, or the braking device and the like based on information about the surroundings of the vehicle, the information being acquired by the vehicle exterior information detection unit 12030 or the vehicle interior information detection unit 12040.

In addition, the microcomputer 12051 can output a control command to the body system control unit 12030 based on the information outside the vehicle acquired by the vehicle exterior information detection unit 12030. For example, the microcomputer 12051 can perform coordinated control for antiglare such as switching a high beam to a low beam by controlling a headlamp according to the position of a preceding vehicle or an oncoming vehicle detected by the vehicle exterior information detection unit 12030.

The audio/image output unit 12052 transmits an output signal of at least one of sound and an image to an output device capable of visually or audibly notifying a passenger or the outside of the vehicle of information. In the example of FIG. 13, an audio speaker 12061, a display unit 12062, and an instrument panel 12063 are shown as examples of the output device. The display unit 12062 may include at least one of an on-substrate display and a head-up display, for example.

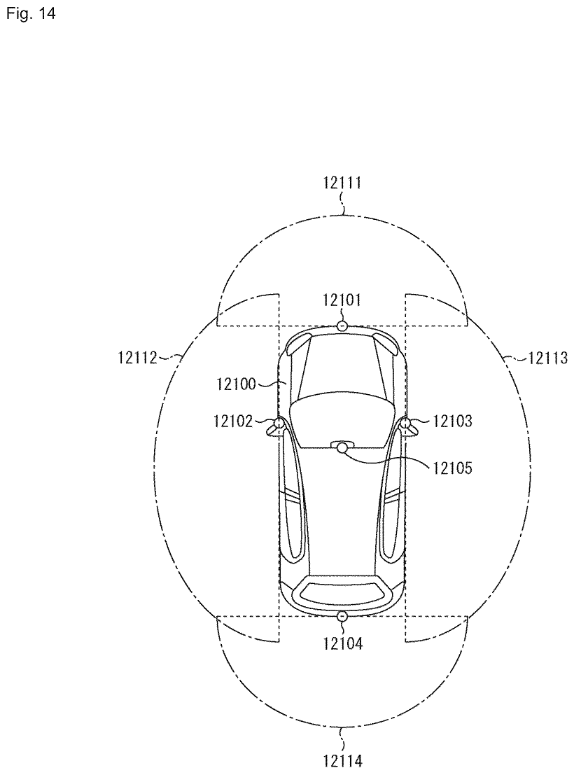

FIG. 14 is a diagram showing an example of the installation positions of imaging units 12031.

In FIG. 14, the imaging unit 12031 includes imaging units 12101, 12102, 12103, 12104, and 12105.

The imaging units 12101, 12102, 12103, 12104, and 12105 are provided at, for example, positions of a front nose, side mirrors, rear bumper, back door, an upper portion of a vehicle's internal front windshield, and the like of the vehicle 12100. The imaging unit 12101 provided on a front nose and the imaging unit 12105 provided in an upper portion of the vehicle's internal front windshield mainly acquire images in front of the vehicle 12100. The imaging units 12102 and 12103 provided in the side mirrors mainly acquire images on the lateral sides of the vehicle 12100. The imaging unit 12104 included in the rear bumper or the back door mainly acquires an image of a region behind the vehicle 12100. The imaging unit 12105 included in the upper portion of the windshield inside the vehicle is mainly used for the detection of a preceding vehicle, a pedestrian, an obstacle, a traffic signal, a traffic sign, a lane, or the like.

FIG. 14 illustrates an example of the imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, the closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by obtaining a distance to each three-dimensional object in the imaging ranges 12111 to 12114 and temporal change in the distance (a relative speed with respect to the vehicle 12100) based on distance information obtained from the imaging units 12101 to 12104. The microcomputer 12051 can also set a following distance to the preceding vehicle to be maintained in advance and perform automatic brake control (including following stop control) and automatic acceleration control (including following start control). It is therefore possible to perform coordinated control for, for example, automated driving in which the vehicle travels in an automated manner without requiring the driver to perform operations.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates the surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the audio/image output unit 12052 controls the display unit 12062 so that a rectangle contour line for emphasis is superimposed and displayed with the recognized pedestrian. In addition, the audio/image output unit 12052 may control the display unit 12062 so that an icon indicating a pedestrian or the like is displayed at a desired position.

The system as used herein refers to an entire device configured by a plurality of devices.

The effects described in the present specification are merely examples and are not limited, and other effects may be obtained.

Embodiments of the present technique are not limited to the above-described embodiment and various modifications can be made within the scope of the present technology without departing from the gist of the present technique.

The present technology can also be configured as follows.
(1)
An imaging element including:
a first photoelectric converter that generates a charge corresponding to an amount of light;
a second photoelectric converter having a smaller light-receiving area than the first photoelectric converter; and
a light-blocking wall provided between adjacent pixels, wherein the light-blocking wall is provided in a shape having a spaced-apart region.
(2)
The imaging element according to (1), wherein
the region is a region where light-blocking walls intersect in a case where the light-blocking walls are provided.
(3)
The imaging element according to (1) or (2), wherein
the light-blocking wall is provided on each side of the first photoelectric converter, one end of the light-blocking wall serves as the region, and the other end is connected to another light-blocking wall.
(4)
The imaging element according to (1) or (2), wherein
the light-blocking walls are provided radially around the second photoelectric converter.
(5)
The imaging element according to (1) or (2), wherein
the light-blocking wall is provided on each side of the first photoelectric converter, and both ends of the light-blocking wall serve as the region.
(6)
The imaging element according to any one of (1), (2), and (5), wherein
the region is not provided on the light-blocking wall provided on each side of the second photoelectric converter.
(7)
The imaging element according to (1) or (2), wherein
the light-blocking wall provided on each side of the first photoelectric converter and the light-blocking wall provided on each side of the second photoelectric converter have the region formed at both ends thereof.
(8)
The imaging element according to (1) or (2), wherein
the first photoelectric converter in which the region is provided and the first photoelectric converter in which the region is not provided are arranged alternately in vertical and horizontal directions.
(9)
The imaging element according to any one of (1) to (8), wherein
the first photoelectric converter is octagonal, and the second photoelectric converter is rectangular.
(10)
The imaging element according to (1), wherein
the first photoelectric converter has an L-shape in plan view,
the second photoelectric converter has a rectangular shape, and
a shape formed by combining the first photoelectric converter and the second photoelectric converter is a rectangular shape.
(11)
The imaging element according to (10), wherein
the light-blocking wall is provided on each side of the first photoelectric converter,
one end of the light-blocking wall serves as the region, and the other end is connected to another light-blocking wall.
(12)
The imaging element according to (10) or (11), wherein
the light-blocking wall is provided on each side of the second photoelectric converter,
and the light-blocking walls provided on two of the sides have at both ends thereof the region.
(13)
An electronic apparatus including:
an imaging element including:
a first photoelectric converter that generates a charge corresponding to an amount of light;
a second photoelectric converter having a smaller light-receiving area than the first photoelectric converter; and
a light-blocking wall provided between adjacent pixels,
the light-blocking wall being provided in a shape having a spaced-apart region; and
a processor that processes signals from the imaging element.

### REFERENCE SIGNS LIST

10 Imaging device
11 Pixel array unit
12 Vertical driver
13 Column processor
14 Horizontal driver
15 System controller
16 Pixel drive line
17 Vertical signal line
18 Signal processor
19 Data storage unit
100 Unit pixel
101 First photoelectric converter
102 Second photoelectric converter
103 First transfer transistor
104 Second transfer transistor
105 Third transfer transistor
106 Fourth transfer transistor
107 FD unit
108 Reset transistor
109 Amplification transistor
110 Selection transistor
111 Charge accumulation unit
112 Node
113 Node
121 Current source
151 Light-blocking wall
201 Pixel
202 Light-blocking wall
203 Light-blocking wall
211 Semiconductor substrate
251 Light-blocking wall
252 Light-blocking wall
301 Light-blocking wall
351 Light-blocking wall
401 First photoelectric converter
402 Second photoelectric converter
421 Light-blocking wall
451 Light-blocking wall

1. An imaging element comprising:
a first photoelectric converter that generates a charge corresponding to an amount of light;
a second photoelectric converter having a smaller light-receiving area than the first photoelectric converter; and
a light-blocking wall provided between adjacent pixels, wherein
the light-blocking wall is provided in a shape having a spaced-apart region.

2. The imaging element according to claim 1, wherein
the region is a region where light-blocking walls intersect in a case where the light-blocking walls are provided.

3. The imaging element according to claim 1, wherein
the light-blocking wall is provided on each side of the first photoelectric converter,
one end of the light-blocking wall serves as the region, and the other end is connected to another light-blocking wall.

4. The imaging element according to claim 1, wherein
the light-blocking walls are provided radially around the second photoelectric converter.

5. The imaging element according to claim 1, wherein
the light-blocking wall is provided on each side of the first photoelectric converter,
and both ends of the light-blocking wall serve as the region.

6. The imaging element according to claim 1, wherein
the region is not provided on the light-blocking wall provided on each side of the second photoelectric converter.

7. The imaging element according to claim 1, wherein
the light-blocking wall provided on each side of the first photoelectric converter and
the light-blocking wall provided on each side of the second photoelectric converter have the region formed at both ends thereof.

8. The imaging element according to claim 1, wherein
the first photoelectric converter in which the region is provided and the first photoelectric converter in which the region is not provided are arranged alternately in vertical and horizontal directions.

9. The imaging element according to claim 1, wherein
the first photoelectric converter is octagonal, and the second photoelectric converter is rectangular.

10. The imaging element according to claim 1, wherein
the first photoelectric converter has an L-shape in plan view,
the second photoelectric converter has a rectangular shape, and
a shape formed by combining the first photoelectric converter and the second photoelectric converter is a rectangular shape.

11. The imaging element according to claim 10, wherein
the light-blocking wall is provided on each side of the first photoelectric converter,
one end of the light-blocking wall serves as the region, and the other end is connected to another light-blocking wall.

12. The imaging element according to claim 10, wherein
the light-blocking wall is provided on each side of the second photoelectric converter,
and the light-blocking walls provided on two of the sides have at both ends thereof the region.

13. An electronic apparatus comprising:
an imaging element including
a first photoelectric converter that generates a charge corresponding to an amount of light,
a second photoelectric converter having a smaller light-receiving area than the first photoelectric converter, and
a light-blocking wall provided between adjacent pixels,
the light-blocking wall being provided in a shape having a spaced-apart region; and
a processor that processes signals from the imaging element.
